(19) United States
(12) Patent Application Publication
(10) Pub. No.: US 2025/0046726 A1
(43) Pub. Date: Feb. 6, 2025

(54) SEMICONDUCTOR DEVICES AND METHODS FOR FORMING THE SAME

(71) Applicant: STATS ChipPAC Pte. Ltd., Singapore (SG)

(72) Inventors: MinGyu KIM, Incheon (KR); YoungGeun KIM, Incheon (KR)

(21) Appl. No.: 18/789,713

(22) Filed: Jul. 31, 2024

(30) Foreign Application Priority Data
Aug. 4, 2023 (CN) 2023109760678

(51) Int. Cl. H01L 23/538; H01L 21/48; H01L 23/00; H01L 23/057; H01L 23/31; H01L 23/36; H01L 23/498; H01L 25/00; H01L 25/10

(52) U.S. Cl. CPC H01L 23/5386; H01L 21/4853; H01L 23/057; H01L 23/36; H01L 23/49811; H01L 23/5385; H01L 25/105; H01L 25/50; H01L 23/3107; H01L 24/08; H01L 24/16; H01L 24/32; H01L 24/48; H01L 24/73; H01L 2224/08225; H01L 2224/16227; H01L 2224/32221; H01L 2224/48227; H01L 2224/73253; H01L 2225/1041

(57) ABSTRACT

A semiconductor device comprises: an interconnection substrate having a front side and a back side, wherein the interconnection substrate comprises interconnection structures extending between its front side and back side, and a bridge module embedded within the interconnection substrate and exposed from the back side of the interconnection substrate; a front side semiconductor component mounted at the front side of the interconnection substrate; two backside semiconductor components mounted at the back side of the interconnection substrate, wherein the two backside semiconductor components are electrically coupled to each other and electrically coupled to the front side semiconductor component; a backside encapsulant layer formed at the back side of the interconnection substrate and encapsulating the two backside semiconductor components, wherein the backside encapsulant layer comprises multiple sets of conductive pillars; and conductive bumps mounted at a back side of the backside encapsulant layer and electrically coupled to the interconnection substrate through conductive pillars.

### TECHNICAL FIELD

The present application generally relates to semiconductor packaging technology, and more particularly, to semiconductor devices and methods for forming the same.

### BACKGROUND OF THE INVENTION

The semiconductor industry is constantly faced with complex integration challenges as consumers want their electronics to be smaller, faster and higher performance with more and more functionalities packed into a single device. One of the solutions is Package-on-Package (POP). PoP is a type of packaging method that combines two or more integrated circuit (IC) packages together. In a typical PoP device, two or more packages are vertically connected. The POP devices can more efficiently use space, and reduce lengths of signal paths between the packages. However, signal communication in the conventional POP devices is not satisfactory.

Therefore, a need exists for further improvement to the existing semiconductor devices.

### SUMMARY OF THE INVENTION

An objective of the present application is to provide semiconductor devices with improved signal communication and reduced signal delay.

According to an aspect of the present application, a semiconductor device is provided. The semiconductor device comprises: an interconnection substrate having a front side and a back side, wherein the interconnection substrate comprises interconnection structures extending between its front side and back side, and a bridge module embedded within the interconnection substrate and exposed from the back side of the interconnection substrate; a front side semiconductor component mounted at the front side of the interconnection substrate; two backside semiconductor components mounted at the back side of the interconnection substrate, wherein the two backside semiconductor components are electrically coupled to each other through the bridge module, and electrically coupled to the front side semiconductor components through the interconnection structures; a backside encapsulant layer formed at the back side of the interconnection substrate and encapsulating the two backside semiconductor components, wherein the backside encapsulant layer comprises multiple sets of conductive pillars passing through the backside encapsulant layer; and conductive bumps mounted at a back side of the backside encapsulant layer and electrically coupled to the interconnection substrate through the sets of conductive pillars.

According to another aspect of the present application, a method for forming a semiconductor device is provided. The method comprise: providing an interconnection substrate, wherein the interconnection substrate comprises interconnection structures extending between its front side and back side and a bridge module embedded therein and exposed from its back side; mounting two backside semiconductor components at the back side of the interconnection substrate, wherein the two backside semiconductor components both cover a portion of the bridge module such that they are electrically coupled with each other through the bridge module; forming a backside encapsulant layer at the back side of the interconnection substrate to encapsulate the two backside semiconductor components; forming multiple sets of conductive pillars at the back side of the interconnection substrate, wherein the sets of conductive pillars pass through the interconnection substrate; and mounting a front side semiconductor component at a front side of the interconnection substrate, wherein the front side semiconductor component is electrically coupled to the two backside semiconductor components through the interconnection structures.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a semiconductor device according to an embodiment of the present application.

FIG. 1B illustrates a portion of the semiconductor device shown in FIG. 1A.

FIGS. 2A to 2J illustrate a method for forming a semiconductor device according to an embodiment of the present application.

FIG. 3 illustrates a semiconductor device according to an embodiment of the present application.

FIG. 4 illustrates a semiconductor device according to an embodiment of the present application.

FIG. 5 illustrates a semiconductor device according to an embodiment of the present application.

FIGS. 6A to 6E illustrate a portion of various steps of a method for forming a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

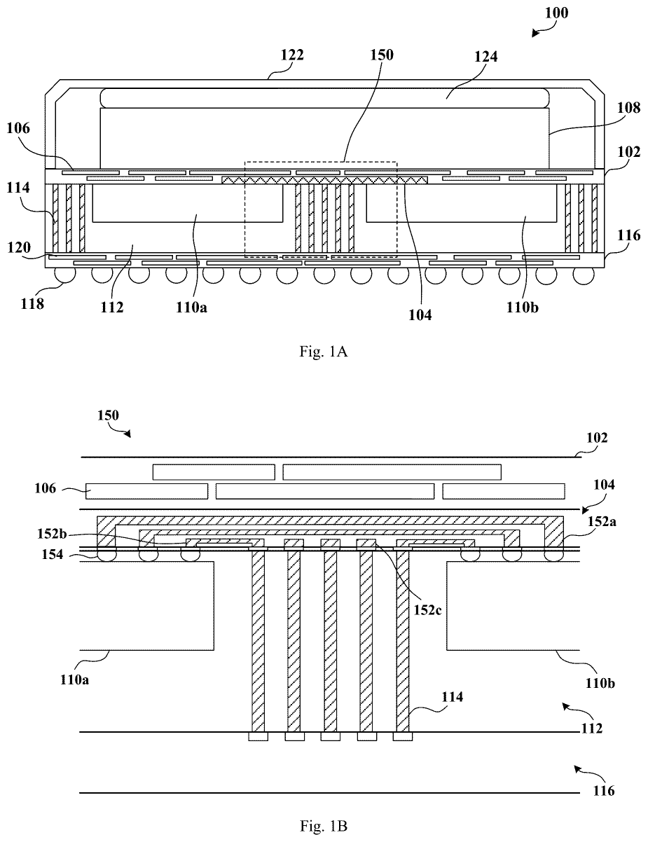

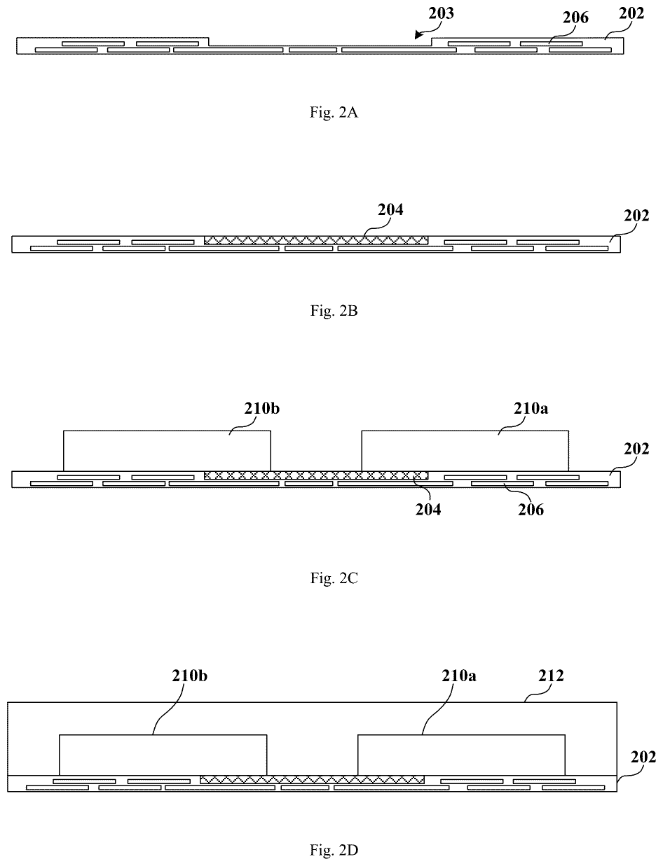

FIG. 1A illustrates a semiconductor device 100 according to an embodiment of the present application. In some embodiments, the semiconductor device 100 may utilize silicon-based interconnection structures to transmit signals between some of its semiconductor components, which can provide a higher speed of signal communication than conventional semiconductor devices.

As shown in FIG. 1A, the semiconductor device 100 includes an interconnection substrate 102, which can provide support and connectivity for electrical components mounted thereon. By way of example, the interconnection substrate 102 can include a printed circuit board (PCB), a carrier substrate, or a ceramic substrate. However, the interconnection substrate 102 is not to be limited to these examples. In some other examples, the interconnection substrate 102 may include a laminate interposer, a strip interposer, a lead frame, or other suitable substrates. The interconnection substrate 102 may include any structure on or in which an integrated circuit system can be fabricated. For example, the interconnection substrate 102 may include one or more insulating or passivation layers, one or more conductive vias formed through the insulating layers, and one or more conductive layers formed over or between the insulating layers, as will be elaborated below in more details.

The interconnection substrate 102 has a front side and a back side, and generally divides the entire semiconductor device 100 into two parts, i.e., a front part at the front side and a back part at the back side. In the embodiment, the interconnection substrate 102 includes a cavity formed at its back side, where a bridge module 104 is embedded. As shown in FIG. 1A, the bridge module 104 has a surface exposed from the back side of the interconnection substrate 102, and is generally flush with a back surface of the interconnection substrate 102. In some embodiments, the bridge module 104 may be generally formed of a silicon substrate, with various through silicon vias (TSVs) that pass through the silicon substrate to transmit signals vertically. That is, the bridge module 104 may be a silicon bridge. The bridge module 104 may also include one or more layers of horizontal conductive materials such as wires, traces or patterns that can electrically connect the TSVs to allow for horizontal connectivity across at least a portion of the bridge module 104. Since the conductive structures in the bridge module 104 can have a higher density and shorter paths than those in non-silicon-based substrates such as printed circuit boards, the bridge module 104 can provide faster speed of signal communication. It can be appreciated that the bridge module 104 may also be formed of a printed circuit board, i.e., generally formed of a polymer compound material, with various horizontal and vertical conductive materials distributed therein. However, a silicon-based substrate is preferred for the bridge module due to the higher density and faster signal communication of such silicon-based substrate.

Besides the bridge module 104, the interconnection substrate 102 also includes interconnection structures 106 such as conductive vias extending between its front side and back side. The interconnection structures 106 can provide electrical path between the two sides of the interconnection substrate 102, to electrically couple a semiconductor component of the front part to another semiconductor component of the back part of the semiconductor device 100. For example, a front side semiconductor component 108 may be mounted at the front side of the interconnection substrate 102. The front side semiconductor component 108 may be mounted on the interconnection substrate 102 directly or through conductive bumps (not shown). The front side semiconductor component 108 may be a bigger semiconductor chip or semiconductor package, and thus occupies a significant portion of the interconnection substrate 102 at its front side. In addition, two backside semiconductor components 110a and 110b may be mounted at the back side of the interconnection substrate 102. The backside semiconductor components 110a and 110b may have a size smaller than the front side semiconductor component 108, and thus they may be vertically aligned with a portion of the front side semiconductor component 108. The backside semiconductor component 110a and 110b can be electrically coupled to the front side semiconductor component 108 through the interconnection structures 106 in the interconnection substrate 102. Similar as the front side semiconductor component 108, the backside semiconductor components 110a and 110b may be semiconductor chips or packages. Furthermore, each of the two backside semiconductor components 110a and 110b may overlap with a portion of the bridge module 104 such that it can be in contact with the bridge module 104 for electrical connection (e.g., indirectly through solder bumps or directly). In this way, the backside semiconductor components 110a and 110b may be electrically coupled with each other through the bridge module 104. That is to say, all the semiconductor components at both sides of the interconnection substrate 102 can be electrically coupled together through the interconnection substrate 102, thereby forming a compact structure and occupying a smaller footprint when the semiconductor device 100 is mounted on a carrier such as a printed circuit board. In particular, the bridge module 104 may be connected with certain interconnection structures 106 above it, to form a vertical electrical path between the front side semiconductor component 108 and the backside semiconductor components 110a and 110b. In some embodiments, the interconnection substrate 102 may have a window where the bridge module 104 is filled, that is, the bridge module 104 may have a thickness equal to that of the interconnection substrate 102. But in some other embodiments, the bridge module 104 may have a thickness smaller than that of the interconnection substrate 102. Then the front side semiconductor component 108 and the backside semiconductor components 110a and 110b can be electrically coupled together through the bridge module 104. It can be seen that the bridge module 104 may function as a “hub” for the semiconductor components of the semiconductor device 100, thereby providing faster signal communication in the semiconductor device 100.

It can be appreciated more front side and backside semiconductor components may be mounted on either side of the interconnection substrate 102, which may be electrically coupled together by either the interconnection structures 106 or the bridge module 104. For example, in case that the bridge module 104 is shaped as a square, four semiconductor components may be mounted at the back side of the interconnection substrate 102 and overlap with respective corners of the bridge module 104. In this way, all these four semiconductor components may be coupled together through the TSVs and other conductive structures within the bridge module 104. Also, two or more bridge modules may be embedded within the interconnect substrate 102, either at the front side or back side, or at both sides, to connect at least some semiconductor components mounted at the same side as the respective bridge modules.

A backside encapsulant layer 112 is formed at the back side of the interconnection substrate 102 to encapsulate the two backside semiconductor components 110a and 110b. The backside encapsulant layer 112 may have a thickness greater than that of the backside semiconductor components 110a and 110b to avoid their exposure from the encapsulant layer 112. The backside encapsulant layer 112 can be a polymer composite material, such as epoxy resin, epoxy acrylate, or any suitable polymer with or without filler. The backside encapsulant layer 112 may be non-conductive, provides structural support, and environmentally protects the semiconductor components 110a and 110b from external elements and contaminants.

The backside encapsulant layer 112 includes multiple sets of conductive pillars 114 which pass through the backside encapsulant layer 112 and are generally in parallel with the backside semiconductor components 110a and 110b, to electrically couple the interconnection substrate 102 with a component or element further below the backside encapsulant layer 112. In the embodiment, a backside substrate 116 is mounted at the back side of the backside encapsulant layer 112, and therefore be electrically coupled to the interconnection substrate 102 through the sets of conductive pillars 114. In addition, conductive bumps 118 may be mounted at the back side of the backside encapsulant layer 112, optionally through the backside substrate 116, to be electrically coupled to the interconnection substrate 102 through the sets of conductive pillars 114 in the backside encapsulant layer 112 and optionally the backside substrate 116. In some embodiments, the backside substrate 116 can include redistribution layers 120 which can redistribute the layout and connection of the conductive bumps 118 with the conductive pillars 114. In some embodiments, at least one set of conductive pillars may be electrically connected to the interconnection structures 106 of the interconnection substrate 102, and in some other embodiments, at least one set of conductive pillars 106 may be connected to the bridge module 104 to provide a fast electrical path between the semiconductor components 110a and 110b and the conductive bumps 118.

A heat spreader lid 122 may be mounted at the front side of the interconnection substrate 102, to cover the front side semiconductor component 108. The heat spreader lid 122 may have a cavity to accommodate the front side semiconductor component 108, and a side wall that is attached onto the front surface of the interconnection substrate 102. In some embodiments, the heat spreader lid 122 may be thermally coupled to the front side semiconductor component 108 through a thermal interface material layer 124 to form a better thermal path therebetween. It can be appreciated that other structures may be formed at the front side of the interconnection substrate 102. For example, a front side encapsulant layer and optionally an electromagnetic interference (EMI) shielding layer (not shown) may be alternatively formed to encapsulate and protect the front side semiconductor component 108.

FIG. 1B illustrates a portion 150 of the semiconductor device 100 shown in FIG. 1A, especially the bridge module 104 and its connection to the other components of the semiconductor device 100.

As shown in FIG. 1B, the two backside semiconductor components 110a and 110b are encapsulated in the backside encapsulant layer 112. In the embodiment, the backside semiconductor components 110a and 110b may be mounted on the interconnection substrate 102 through solder bumps 154, and then be under filled and encapsulated by the backside encapsulant layer 112. The solder bumps 154 may be aligned with contact pads exposed from the interconnection substrate 102. Furthermore, various conductive pillars 114 may be encapsulated by the backside encapsulant layer 112 as well, which may pass through the entire encapsulant layer 112 in its thickness direction to allow for electrical connection between two surfaces of the encapsulant layer 112. For example, the conductive pillars 114 may be in the form of through vias.

In the embodiment, the bridge module 104 may include a silicon substrate, with conductive wires distributed therein. For example, multiple first conductive wires 152a may be formed in the silicon substrate to connect the solder bumps 154 attached to the backside semiconductor components 110a with the solder bumps 154 attached to the backside semiconductor components 110b. In this way, the two backside semiconductor components 110a and 110b can be electrically coupled with each other to transmit signals therebetween directly. Furthermore, multiple second conductive wires 152b may be formed in the silicon substrate to connect the solder bumps 154 attached to one of the backside semiconductor components to the conductive pillars 114. As such, the backside semiconductor components 110a and/or 110b can be electrically coupled to the backside substrate 116 through the bridge module 104 and the conductive pillars 114. Furthermore, some conductive wires 152c (with only a portion shown in FIG. 1B) may be electrically coupled between the conductive pillars 114 and the interconnection structures 106 in the interconnection substrate 102, such that other components mounted on the interconnection substrate 102 such as the front side semiconductor component (not shown) may be electrically coupled to the backside substrate 116 through the interconnection structures 106, the conductive wires 152c and the conductive pillars 114.

As can be seen from FIG. 1B, the various configurations of the conductive wires 152a, 152b and 152c in the bridge module provide flexibility in electrically connecting the components of the semiconductor device. That is, the bridge module functions as an interposer in the semiconductor device. In some embodiments where the bridge module is formed of a silicon substrate, faster signal transmission in the bridge module can be implemented due to shorter electrical paths. It can be appreciated that the embodiment shown in FIG. 1B are only exemplary, and various modifications may be made to the bridge module (especially its conductive wires) shown in FIG. 1B.

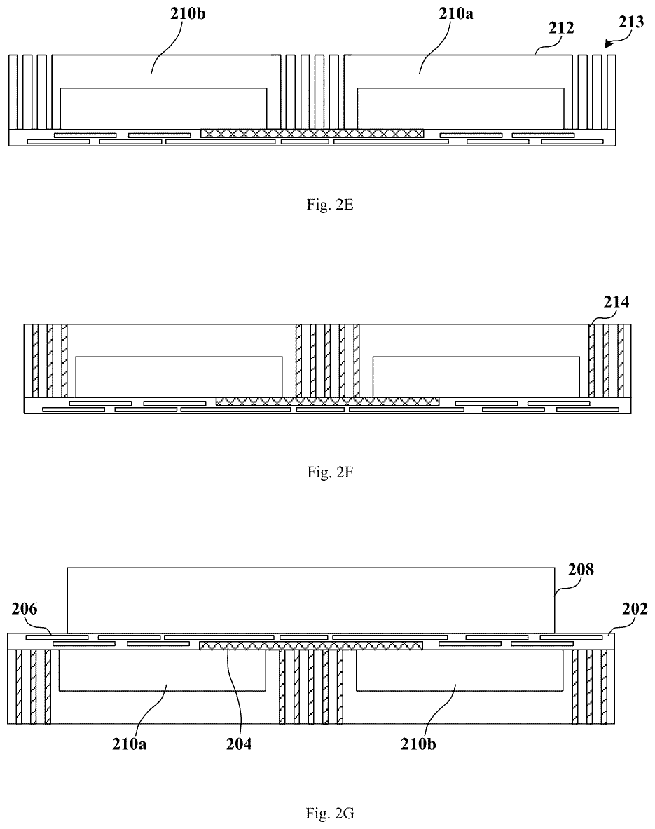

FIGS. 2A to 2J illustrate various steps of a method for forming a semiconductor device according to an embodiment of the present application. For example, the method can be used to form the semiconductor device 100 shown in FIG. 1A.

As shown in FIG. 2A, an interconnection substrate 202 is provided. The interconnection substrate 202 includes various interconnection structures 206 extending between its front side and back side. In some embodiments, a portion of the interconnection structures 206 may be further connected with another portion of the interconnection structures 206 through horizontal conductive structures in the interconnection substrate 202. A cavity 203 may be formed at the back side of the interconnection substrate 202, to receive a bridge module (not shown). The size and shape of the cavity 203 may depend on the position of backside semiconductor components to be connected by the bridge module. As shown in FIG. 2B, a bridge module 204 is filled in the cavity and thus embedded in the interconnection substrate 202. For example, an adhesive material may be filled in the cavity to help the bridge module 204 firmly filled in the cavity. The bridge module 204 may be preformed using an integrated circuit fabrication process, if it is formed of a silicon-based material.

Next, as shown in FIG. 2C, two backside semiconductor components 210a and 210b are mounted on the interconnection substrate 202. Each of the two backside semiconductor components 210a and 210b may overlap with a portion of the bridge module 204 and thus be in electrical connection with the bridge module 204. The two backside semiconductor components 210a and 210b can also be electrically coupled with each other through the bridge module 204 due to the horizontal connectivity of the bridge module 204. In some embodiments, the backside semiconductor components 210a and 210b may also be electrically connected with the interconnection structures 206 of the interconnection substrate 202. For example, the backside semiconductor components 210a and 210b may have contact pads that can be bonded with contact pads on the back surface of the interconnection substrate 202. In some optional embodiments, conductive bumps or similar structures may be formed between the backside semiconductor components 210 and 210b and the interconnection substrate 202.

Next, as shown in FIG. 2D, a backside encapsulant layer 212 may be formed on the interconnection substrate 202 to cover the two backside semiconductor components 210a and 210b. For example, the backside encapsulant layer 212 may be formed using injection molding, compressive molding, transfer molding, liquid encapsulant molding, vacuum lamination, spin coating, or another suitable processes.

Next, as shown in FIG. 2E, multiple sets of trenches 213 may be formed through the backside encapsulant layer 212 at positions where the backside semiconductor components 210a and 210b are not mounted. In some embodiments, the trenches 213 may be formed using laser ablation or etching. Then a conductive material such as copper may be filled in the trenches to form multiple sets of conductive pillars 214, as shown in FIG. 2F. The conductive pillars 214 may pass through the interconnection substrate 202. If an excess portion of the conductive material is deposited in the trenches and covers the back surface of the encapsulant layer 212, an etching process may be performed to remove the excess conductive material.

Next, as shown in FIG. 2G, the interconnection substrate 202 is flipped over, with its backside facing downward. Then a front side semiconductor component 208 may be mounted at the front side of the interconnection substrate 202. The front side semiconductor component 208 may be mounted on the front surface of the interconnection substrate 202 direct or indirectly via conductive bumps or similar structures (not shown). The front side semiconductor component 208 can be electrically connected with the interconnection substrate 202. In some embodiments, the front side semiconductor component 208 can be electrically coupled to the two backside semiconductor components 210a and 210b through the interconnection structures 206. In some optional embodiments, the front side semiconductor component 208 can be further electrically coupled to the bridge module 204 through the interconnection structures 206, such that the semiconductor components at both sides of the interconnection substrate 202 can be electrically coupled together mainly through the bridge module 204.

Next, as shown in FIG. 2H, a thermal interface material layer 224 may be formed at a front side of the front side semiconductor component 208. For example, the thermal interface material may be dispensed onto the front surface of the front side semiconductor component 208. The thermal interface material is used for enhancing thermal coupling between the front side semiconductor component 208 and a heat spreader lid to be attached. In some embodiments, the thermal interface material can be thermally conductive, dispensable materials, preferably thermal greases, thermal adhesives, thermal gap fillers, liquid metal, and solder paste. In an embodiment, the thermal interface material is an epoxy compound, which may be used for easy bonding to metals, ceramics, most plastics and a wide variety of other materials. In another embodiment, the thermal interface material includes solder paste which has improved thermal conductivity over typical thermal interface material. Preferably, the solder paste is Ag-In solder alloy. Specifically, the thermal interface material may be a solder preform, that is, a solid, flat, manufactured-shape of solder, and a flux may be applied to coat the solder preform. Afterwards, a metal spreader lid 222 may be attached on the interconnection substrate 202 to cover the front side semiconductor component 208. The metal spreader lid 222 is usually made of a high thermal conductive metallic material for efficient heat dissipation from the front side semiconductor component to the external space. In the embodiment, the metal spreader lid 222 may work in combination with the thermal interface material layer 224 to provide better heat dissipation for the semiconductor components inside the semiconductor device. The metal spreader lid 222 is preferably made of copper, aluminum, and copper-tungsten alloy. It can be appreciated that other suitable materials can be used to form the metal spreader lid 222.

Next, as shown in FIG. 2I, a backside substrate 216 may be attached on the backside encapsulant layer 212, for example, using a bonding process. The backside substrate 216 has redistribution layers 220 that may be electrically connected to the respective sets of conductive pillars 214 that pass through the backside encapsulant layer 212.

Next, as shown in FIG. 2J, the interconnection substrate 202 and components mounted thereon are flipped over, with its front side facing downward. Conductive bumps 218 may be mounted at the back side of the backside encapsulant layer 212, for example, using a surface mounting process. As such, the conductive bumps 218 are electrically coupled to the interconnection substrate 202 through the respective conductive pillars 216. In this way, the semiconductor device incorporating various semiconductor components that are interconnected using the bridge module and/or interconnection structures can be formed.

In some embodiments, the backside substrate 216 may be omitted. In that case, conductive bumps 218 may be mounted directly at the back side of the backside encapsulant layer 212. However, the conductive bumps 218 need to be vertically aligned with the conductive pillars 214 in the backside encapsulant layer 212.

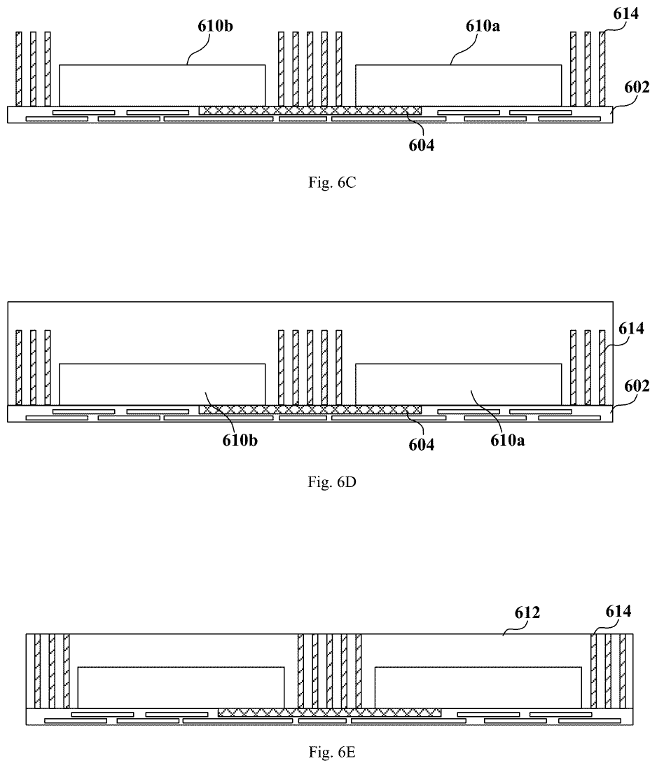

In some embodiments, the components at the back side of the interconnection substrate 202 can be formed in a manner different from those steps shown in FIGS. 2B to 2F. FIGS. 6A to 6E illustrate a portion of various steps of a method for forming a semiconductor device according to an embodiment of the present application.

As shown in FIG. 6A, an interconnection substrate 602 with a bridge module 604 embedded therein is provided. Next, as shown in FIG. 6B, multiple sets of conductive pillars 614 may be attached onto the interconnection substrate 602 at the same side of the bridge module 604. In some embodiments, a portion of the sets of conductive pillars 614 may be connected with the bridge module 604 to establish electrical connection with the bridge module 604, for example, through solder bumps or through bonding.

Next, as shown in FIG. 6C, two backside semiconductor components 610a and 610b can be attached onto the interconnection substrate 602 at the same side as the conductive pillars 614. The backside semiconductor components 610a and 610b overlap with a respective portion of the bridge module 604 so that they are also electrically coupled with each other through the bridge module 604 due to the horizontal connectivity of the bridge module 604. In some embodiments, the backside semiconductor components 610a and 610b may also be electrically connected with interconnection structures of the interconnection substrate 602 besides the bridge module 604, for example, through solder bumps or through bonding. It can be appreciated that the backside semiconductor components 610a and 610b may have a thickness smaller than that of the conductive pillars 614.

Next, as shown in FIG. 6D, a backside encapsulant layer 612 may be formed on the interconnection substrate 602 to cover the two backside semiconductor components 610a and 610b and the sets of conductive pillars 614. For example, the backside encapsulant layer 612 may be formed using injection molding, compressive molding, transfer molding, liquid encapsulant molding, vacuum lamination, spin coating, or another suitable processes. In some embodiments, the backside encapsulant layer 612 after the molding process may have a thickness equal to that of the conductive pillars 614 so that an additional molding planarizing or etching process may not be needed. In some alternative embodiments such as that shown in FIG. 6D, the backside encapsulant layer 612 may have a thickness greater than that of the conductive pillars 614, a molding planarizing or etching process may be desired to remove the excess molding material, as shown in FIG. 6E.

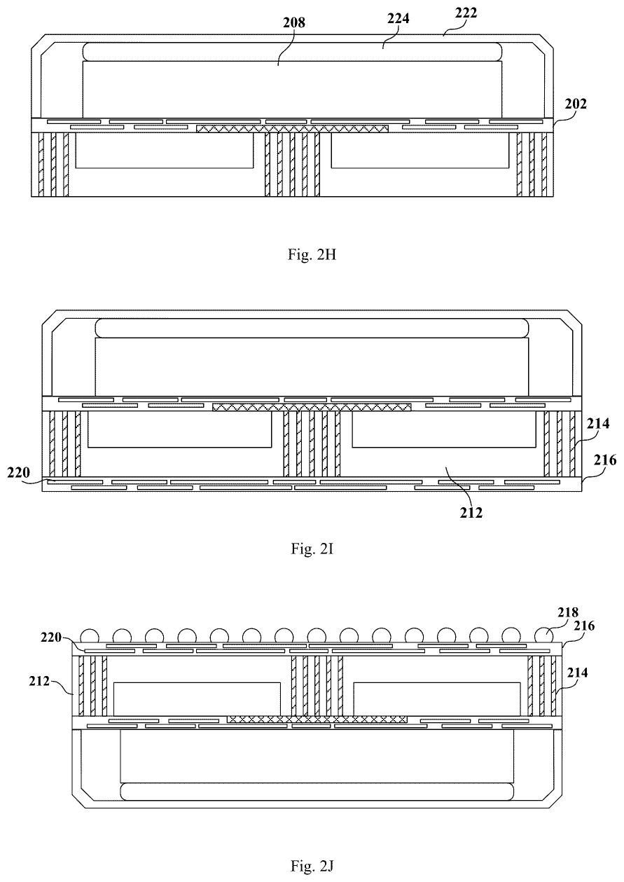

FIG. 3 illustrates a semiconductor device 300 according to an embodiment of the present application.

As shown in FIG. 3, different from the semiconductor device 100 shown in FIG. 1A, the semiconductor device 300 does not include a heat spreader lid. Instead, a front side encapsulant layer 328 is formed at a front side of an interconnection substrate 302, to encapsulate a front side semiconductor component 308 mounted on the interconnection substrate 302. In addition, bonding wires 326 may be attached between a front side of the front side semiconductor component 308 and the front side of the interconnection substrate 302 to electrically couple them together. In this way, the front side semiconductor component 308 can be electrically coupled to backside semiconductor components 310a and 310b through the bonding wires 326 and interconnection structures 306 inside the interconnection substrate 302. In some embodiments, the bonding wires 326 may be first formed on the interconnection substrate 302 and then be encapsulated by the front side encapsulant layer 328 along with the front side semiconductor component 308.

Furthermore, different from the semiconductor device 100 shown in FIG. 1A which includes a backside substrate 116, the semiconductor device 300 does not have the backside substrate such that conductive bumps 318 are respectively connected to conductive pillars 314 inside a backside encapsulant layer 312, and the interconnection substrate 302 can be electrically coupled to the conductive bumps 318 underneath the entire semiconductor device 300.

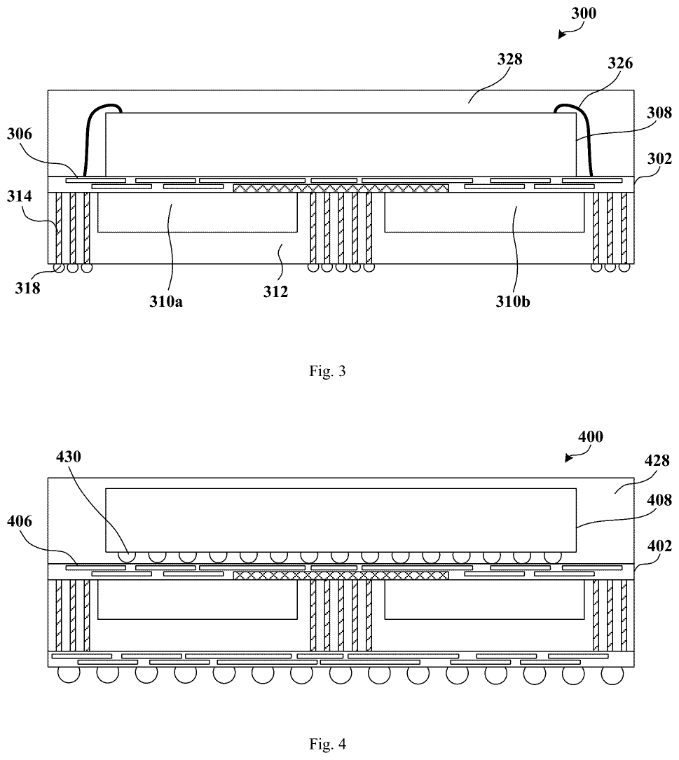

FIG. 4 illustrates a semiconductor device 400 according to an embodiment of the present application.

As shown in FIG. 4, similar as the semiconductor device 300 shown in FIG. 3, the semiconductor device 400 includes a front side encapsulant layer 428 which encapsulates a front side semiconductor component 408 on a front side of an interconnection substrate 402. In particular, the front side semiconductor component 408 is mounted on the interconnection substrate 402 through a set of conductive bumps 430 which facilitate the mounting of the front side semiconductor component 408. The conductive bumps 430 can be connected with contact pads exposed from the interconnection substrate 402 to be electrically coupled with interconnection structure 406 in the interconnection substrate 402.

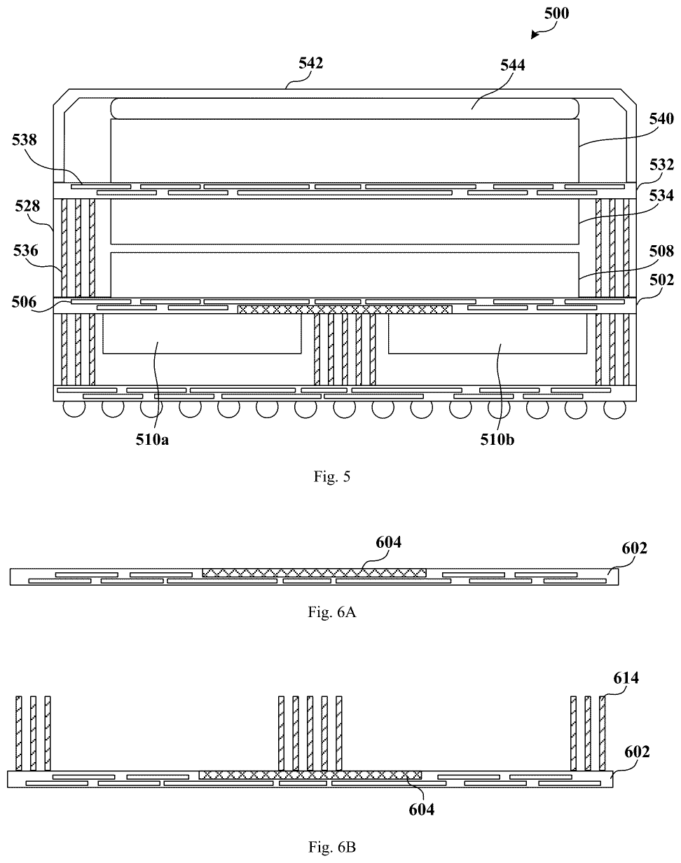

FIG. 5 illustrates a semiconductor device 500 according to an embodiment of the present application. The semiconductor device 500 includes more layers of semiconductor components compared with the two layers of semiconductor components as shown in FIGS. 1, 3 and 4. Accordingly, more substrates may be stacked to provide for connection between the semiconductor components.

As shown in FIG. 5, the semiconductor device 500 includes an interconnection substrate 502 where a front side semiconductor component 508 is mounted. The front side semiconductor component 508 is encapsulated by a front side encapsulant layer 528. At a front side of the front side encapsulant layer 528, a top substrate 532 is mounted. Multiple sets of top conductive pillars 536 may be mounted at the front side of the interconnection substrate 502, which pass through the front side encapsulant layer 528. In this way, the top conductive pillars 536 may electrically couple the top substrate 532 with the interconnection substrate 502, or particularly interconnection structures 506 and 538 within respective one of the top substrate 532 and the interconnection substrate 502.

Similar as the front side semiconductor component 508 shown in FIG. 1A, a top semiconductor component 540 may be mounted at a front side of the top substrate 532. Moreover, a heat spreader lid 542 may be mounted at the front side of the top substrate 532 to cover the top semiconductor component 540. The heat spreader lid 542 may be thermally coupled to the top semiconductor component 532 through a thermal interface material layer 544.

In some embodiments, at a back side of the top substrate 532, another semiconductor component 534 may be mounted, which is opposite to the front side semiconductor component 508. Both of the semiconductor component 534 and the front side semiconductor component 508 are encapsulated by the front side encapsulant layer 528, and they are not in contact with each other. Due to the existence of connected interconnection substrate 502 and top substrate 532, all the various semiconductor components 540, 534, 508, 510a and 510b can be electrically coupled together, thereby forming a compact structure. It can be appreciated that more layers of semiconductor components can be integrated within the semiconductor device 500 if more substrates and conductive pillars can be included.

While the exemplary semiconductor devices of the present application is described in conjunction with corresponding figures, it will be understood by those skilled in the art that modifications and adaptations to the method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor device, comprising:
an interconnection substrate having a front side and a back side, wherein the interconnection substrate comprises interconnection structures extending between its front side and back side, and a bridge module embedded within the interconnection substrate and exposed from the back side of the interconnection substrate;
a front side semiconductor component mounted at the front side of the interconnection substrate;
two backside semiconductor components mounted at the back side of the interconnection substrate, wherein the two backside semiconductor components are electrically coupled to each other through the bridge module, and electrically coupled to the front side semiconductor component through the interconnection structures;
a backside encapsulant layer formed at the back side of the interconnection substrate and encapsulating the two backside semiconductor components, wherein the backside encapsulant layer comprises multiple sets of conductive pillars passing through the backside encapsulant layer; and
multiple sets of conductive bumps mounted at a back side of the backside encapsulant layer and electrically coupled to the interconnection substrate through the sets of conductive pillars.

2. The semiconductor device of claim 1, wherein at least one set of conductive pillars are connected to the bridge module.

3. The semiconductor device of claim 1, wherein the bridge module is further electrically coupled to the front side semiconductor component.

4. The semiconductor device of claim 1, wherein the interconnection substrate comprises a cavity at its back side, and the bridge module is embedded in the cavity.

5. The semiconductor device of claim 1, further comprising a backside substrate mounted between the backside encapsulant layer and the conductive bumps.

6. The semiconductor device of claim 1, further comprising a heat spreader lid mounted at the front side of the interconnection substrate and covering the front side semiconductor component, wherein the heat spreader lid is thermally coupled to the front side semiconductor component through a thermal interface material layer.

7. The semiconductor device of claim 1, wherein the front side semiconductor component is mounted on the interconnection substrate directly or through conductive bumps.

8. The semiconductor device of claim 1, further comprising bonding wires attached between a front side of the front side semiconductor component and the front side of the interconnection substrate.

9. The semiconductor device of claim 1, further comprising a front side encapsulant layer at the front side of the interconnection substrate and encapsulating the front side semiconductor component.

10. The semiconductor device of claim 9, further comprising:
multiple sets of top conductive pillars mounted at the front side of the interconnection substrate and passing through the front side encapsulant layer;
a top substrate mounted at a front side of the front side encapsulant layer and electrically coupled to the sets of top conductive pillars; and
a top semiconductor component mounted at a front side of the top substrate.

11. The semiconductor device of claim 10, further comprising a semiconductor component mounted at a back side of the top substrate and opposite to the front side semiconductor component, and the semiconductor component and the front side semiconductor component are both encapsulated by the front side encapsulant layer.

12. The semiconductor device of claim 10, further comprising a heat spreader lid mounted at the front side of the top substrate and covering the top semiconductor component, wherein the heat spreader lid is thermally coupled to the top semiconductor component through a thermal interface material layer.

13. The semiconductor device of claim 1, wherein the bridge module is a silicon bridge.

14. A method for forming a semiconductor device, comprising:
providing an interconnection substrate, wherein the interconnection substrate comprises interconnection structures extending between its front side and back side and a bridge module embedded therein and exposed from its back side;
mounting two backside semiconductor components at the back side of the interconnection substrate, wherein the two backside semiconductor components both cover a portion of the bridge module such that they are electrically coupled with each other through the bridge module;
forming a backside encapsulant layer at the back side of the interconnection substrate to encapsulate the two backside semiconductor components;
forming multiple sets of conductive pillars at the back side of the interconnection substrate, wherein the sets of conductive pillars pass through the interconnection substrate; and
mounting a front side semiconductor component at a front side of the interconnection substrate, wherein the front side semiconductor component is electrically coupled to the two backside semiconductor components through the interconnection structures.

15. The method of claim 14, providing an interconnection substrate further comprising:
forming a cavity at the back side of the interconnection substrate; and
filling the bridge module in the cavity.

16. The method of claim 14, further comprising:
forming a thermal interface material layer at a front side of the front side semiconductor component;
attaching a heat spreader lid on the interconnection substrate to cover the front side semiconductor component, wherein the front side semiconductor component is thermally coupled to the heat spreader lid through the thermal interface material layer;
attaching a backside substrate to the backside encapsulant layer; and
forming conductive bumps at a back side of the backside encapsulant layer, wherein the conductive bumps are electrically coupled to the interconnection substrate through the sets of conductive pillars.

17. The method of claim 14, wherein the bridge module is a silicon bridge.
